(19) United States
(12) Patent Application Publication
(10) Pub. No.: US 2010/0117699 A1
(43) Pub. Date: May 13, 2010

(54) PWM Controller with Frequency Jitter Functionality and Related Method

(76) Inventors: Chi-Hao Wu, Taipei City (TW); Wei-Ching Lee, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/268,450

(22) Filed: Nov. 11, 2008

(51) Int. Cl. H03K 5/04

(52) U.S. Cl. 327/172

(57) ABSTRACT

A pulse width modulation controller with frequency jitter functionality includes an oscillator and a threshold voltage generator. The oscillator is utilized for generating a switching frequency signal according to an upper threshold voltage and a lower threshold voltage. The threshold voltage generator is coupled to the oscillator, and is utilized for generating the upper threshold voltage and the lower threshold voltage and modulating at least one of the upper threshold voltage and the lower threshold voltage to vary over time for jittering the switching frequency signal.

### BACKGROUND OF THE INVENTION

1. Field of the Invention

The present invention relates to a pulse width modulation (PWM) controller with frequency jitter functionality and related method for reducing electromagnetic interference (EMI) of a switching power supply.

2. Description of the Prior Art

Power supplies, converting an AC mains voltage to a DC voltage, are wildly used in integrated electronic devices. The power supplies are required to maintain the output voltage, current or power within a regulated range for efficient and safe operation of the electronic device, and thus switches that operate according to a pulse width modulated (PWM) control are employed.

Please refer to FIG. 1. FIG. 1 is a schematic diagram of a traditional power supply 10. Generally, the power supply 10 includes a transformer 100, a transistor 102, a PWM controller 104, an opto-coupler 106 and an error amplifier 108. The PWM controller 104 generates a switching signal V_{PWM} for switching the transformer 100 via the transistor 102. The duty cycle of the switching signal V_{PWM} determines the power delivered from a primary winding Np to a second winding Ns of the transformer 100, and thus, in order to keep the secondary DC voltage within a regulated range, a feedback loop including the opto-coupler 106 and the error amplifier 108 provides a feedback voltage VFB to vary the duty cycle of the switching signal V_{PWM}.

A problem of utilizing PWM controllers is that they operate at a relatively high frequency compared to the frequency of the AC mains voltage, which results in a high frequency signal being generated by the power supply. This high frequency signal is injected back into the AC mains input and becomes a component of the AC mains signal. The high frequency signal and its harmonics are also radiated by the power supply as electromagnetic waves, which in fact are the largest contributors to the Electromagnetic Interference (EMI) of the power supply. The EMI generated by the power supply can cause problems for communication devices in the vicinity of the power supply, and the high frequency signal which becomes a component of the AC mains signal will be provided to other devices in the power grid, which also causes noise problems for those devices. Further, the radiated EMI by the power supply can interfere with radio and television transmissions that are transmitted over the air by various entities.

Thus, in order to combat the EMI problem, a jittered clock source is often utilized to be the operation frequency of the PWM switch, which allows the switching frequency spreading over a larger bandwidth, so as to minimize the peak value of the EMI generated by the power supply. However, since the jittered clock source is generally generated by adding a time-varying signal such as a time-varying current or a time-varying capacitance to an oscillation frequency of an oscillator, external frequency generation circuits in addition to the oscillator are required to generate the time-varying signal in the PWM controllers. Therefore, the size and cost of the power supply are increased.

### SUMMARY OF THE INVENTION

It is therefore an objective of the present invention to provide a PWM controller with frequency jitter functionality to reduce EMI of a power supply.

According to the present invention, a PWM controller with frequency jitter functionality is disclosed. The PWM controller includes an oscillator and a threshold voltage generator. The oscillator is utilized for generating a switching frequency signal according to an upper threshold voltage and a lower threshold voltage. The threshold voltage generator is coupled to the oscillator, and is utilized for generating the upper threshold voltage and the lower threshold voltage and modulating at least one of the upper threshold voltage and the lower threshold voltage to vary over time for jittering the switching frequency signal.

According to the present invention, a PWM controller with frequency jitter functionality is further disclosed. The PWM controller includes an oscillator and a voltage divider. The oscillator is utilized for generating a switching frequency signal according to an upper threshold voltage and a lower threshold voltage. The voltage divider is coupled to the oscillator, and is utilized for performing a voltage-dividing operation on a power supply voltage to generate the upper threshold voltage and the lower threshold voltage, and modulating both of the upper threshold voltage and the lower threshold voltage to vary over time due to glitches of the power supply voltage those suddenly drop by charging or discharging rear end loads in order for jittering the switching frequency signal.

According to the present invention, a frequency jitter method for a PWM controller is further disclosed. The frequency jitter method includes the steps of generating a switching frequency signal according to an upper threshold voltage and a lower threshold voltage of an oscillator, and modulating at least one of the upper threshold voltage and the lower threshold voltage to vary over time for jittering the switching frequency signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a traditional power supply.

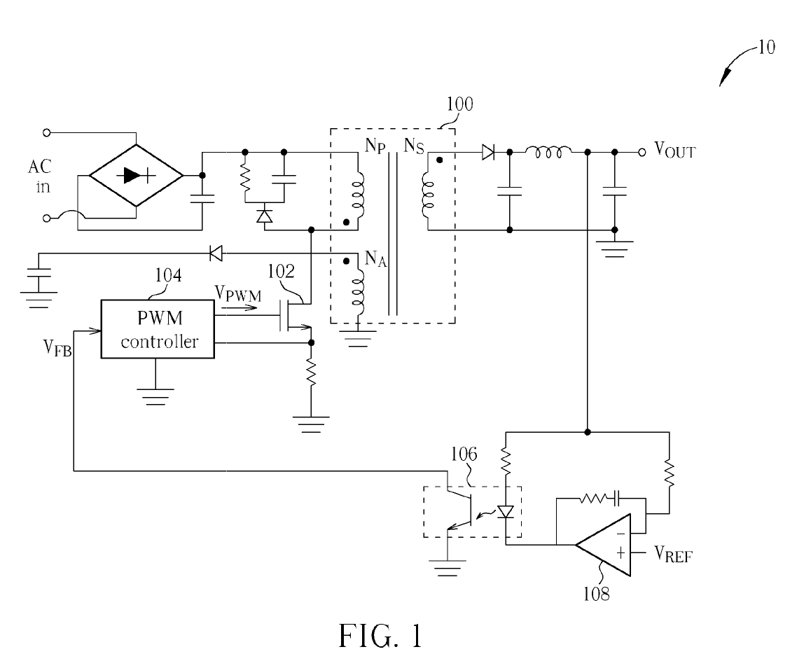

FIG. 2 is a schematic diagram of a PWM controller with frequency jitter functionality according to an embodiment of the present invention.

FIG. 3 shows an exemplary embodiment of the threshold voltage generator in FIG. 2.

FIG. 4 is a timing diagram of an upper threshold voltage, a lower threshold voltage, a saw-tooth wave and a switching frequency signal related to FIG. 3.

FIG. 5 shows another exemplary embodiment of the threshold voltage generator in FIG. 2.

FIG. 6 also shows an exemplary embodiment of the threshold voltage generator in FIG. 2.

FIG. 7 is a timing diagram of an upper threshold voltage, a lower threshold voltage, a saw-tooth wave and a switching frequency signal related to FIG. 5 and FIG. 6.

FIG. 8 is a schematic diagram of a frequency jitter process for a PWM controller according to an embodiment of the present invention.

### DETAILED DESCRIPTION

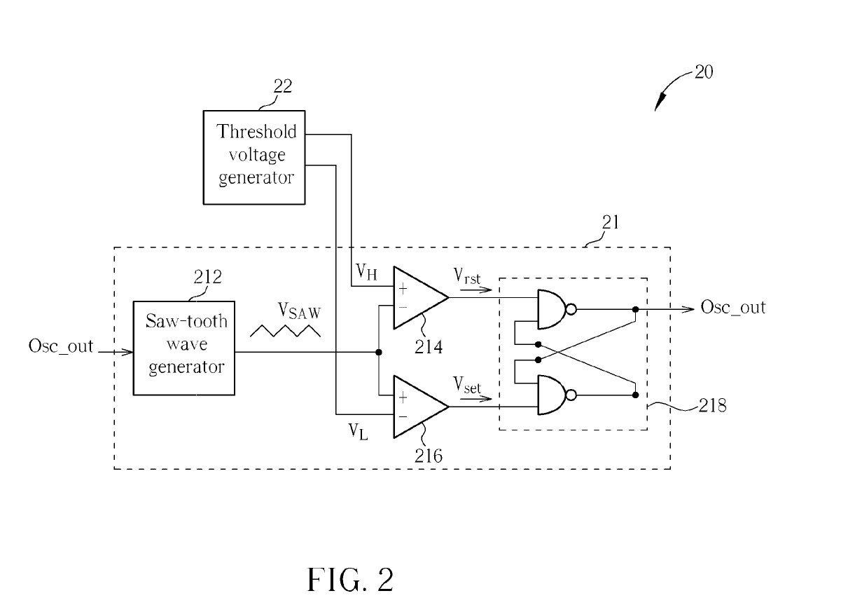

Please refer to FIG. 2. FIG. 2 is a schematic diagram of a pulse width modulation (PWM) controller 20 with frequency jitter functionality according to an embodiment of the present invention. The PWM controller 20 is utilized for controlling a switching power supply, and includes an oscillator 21 and a threshold voltage generator 22. The oscillator 21 is utilized for generating a switching frequency signal osc_out according to an upper threshold voltage V_{H} and a lower threshold voltage V_{L}, and includes a saw-tooth wave generator 212, a first comparator 214, a second comparator 216 and an RS latch 218. The saw-tooth wave generator 212 is utilized for generating a saw-tooth wave V_{SAW}. The first comparator 214 has a positive input terminal coupled to the upper threshold voltage V_{H} and a negative input terminal coupled to the saw-tooth wave generator 212, and is utilized for generating a reset signal Vᵣₛₜ when the saw-tooth wave V_{SAW} rises to the upper threshold voltage V_{H}. The second comparator 216 has a positive input terminal coupled to the saw-tooth wave generator 212 and a negative input terminal coupled to the lower threshold voltage V_{L}, and is utilized for generating a set signal Vₛₑₜ when the saw-tooth wave V_{SAW} descends to the lower threshold voltage V_{L}. The RS latch 218 has a reset terminal coupled to the first comparator 214 and a set terminal coupled to the second comparator 216, and is utilized for generating the switching frequency signal osc_out according to the reset signal Vᵣₛₜ and the set signal Vₛₑₜ. More specifically, the switching frequency signal osc_out is low when the reset signal Vᵣₛₜ is received, and is high when the set signal Vₛₑₜ is received. In addition, the switching frequency signal osc_out is further fed back to the saw-tooth wave generator 212 for controlling the generation of the saw-tooth wave V_{SAW}. Detailed operations of the oscillator 21 are well-known by those skilled in the art, and not narrated herein.

The threshold voltage generator 22 is coupled to the oscillator 21, and is utilized for generating the upper threshold voltage V_{H} and the lower threshold voltage V_{L} of the oscillator 21. Furthermore, the threshold voltage generator 22 modulates at least one of the upper threshold voltage V_{H} and the lower threshold voltage V_{L} to vary over time for jittering the switching frequency signal osc_out generated by the oscillator 21. In other words, by modulating the threshold voltages of the oscillator 21 to vary over time, the time that the saw-tooth wave V_{SAW} takes to reach the threshold voltage also changes as long as the rising or descending slope of the saw-tooth wave V_{SAW} is kept the same, so the frequency generated by the oscillator 21 is also changed. In this case, the operation frequency of the PWM controller 20 can be jittered and spread over a larger bandwidth, so as to minimize the peak value of electromagnetic interference (EMI) generated by a switching power supply.

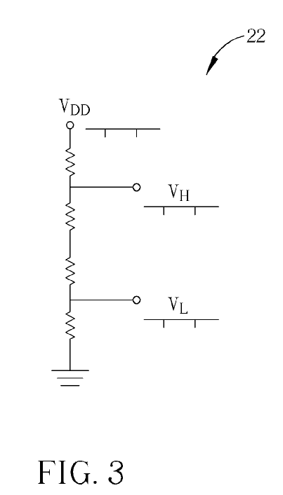

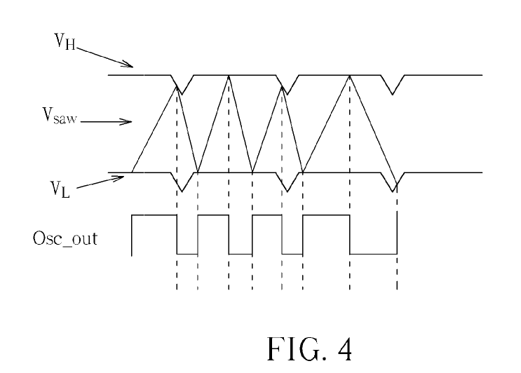

Preferably, the threshold voltage generator 22 can simply be a voltage divider. Please refer to FIG. 3, which shows an exemplary embodiment of the threshold voltage generator 22 of the present invention. As shown in FIG. 3, the threshold voltage generator 22 is a resistance voltage divider, and performs a voltage-dividing operation on a power supply voltage VDD to generate the upper threshold voltage V_{H} and the lower threshold voltage V_{L}. Since the power supply voltage VDD may have some glitches when charging or discharging rear end loads, both of the upper threshold voltage V_{H} and the lower threshold voltage V_{L} are then varied over time by those sudden drops. Therefore, the switching frequency generated by the oscillator 21 can be jittered by the time-varying threshold voltages. Related timing of the upper threshold voltage V_{H}, the lower threshold voltage V_{L}, the saw-tooth wave V_{SAW} and the switching frequency signal osc_out are shown in FIG. 4.

Thus, by taking advantages of the glitches of the power supply voltage VDD, the switching frequency generated by the oscillator 21 can be jittered by the time-varying threshold voltages, and no external frequency generation circuits in addition to the oscillator 21 are required in the PWM controller. Therefore, the size and cost of the power supply can be significantly reduced.

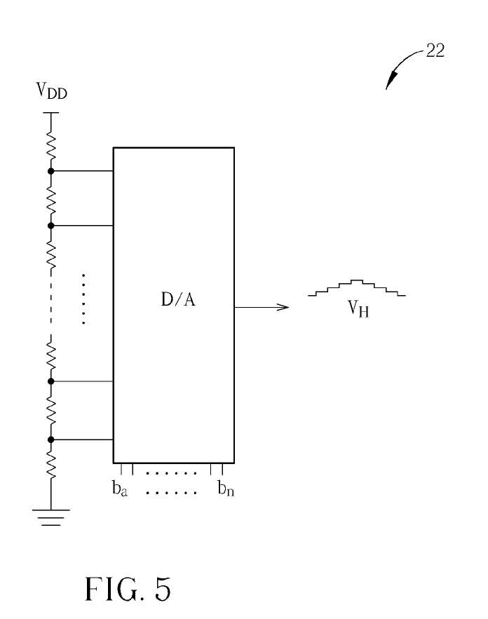

Certainly, the threshold voltage generator 22 can also be realized by other schemes, providing that at least one of the upper threshold voltage V_{H} and the lower threshold voltage V_{L} being varied over time, so as to jitter the switching frequency signal osc_out generated by the oscillator 21. FIG. 5 shows another exemplary embodiment of the threshold voltage generator 22 of the present invention. The threshold voltage generator 22 is a signal converter, performing signal conversion on controllable inputs b₀˜bₙ in order to generate at least one of the time-varying upper threshold voltage V_{H} and the time-varying lower threshold voltage V_{L}. In FIG. 5, the threshold voltage generator 22 is implemented with a digital-to-analog converter as an example, and the controllable inputs b₀˜bₙ are produced by a digital code generator (not shown in FIG. 5).

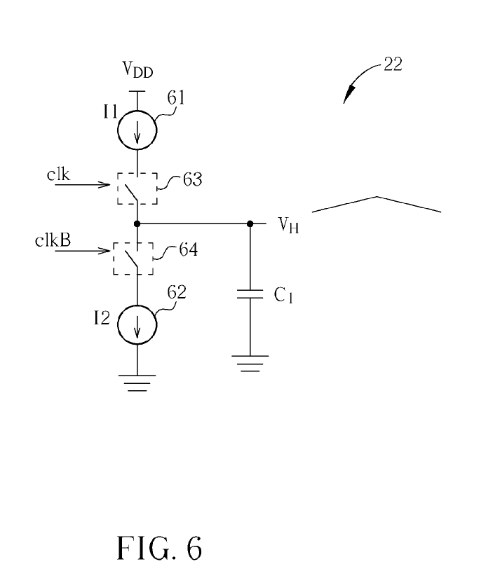

On the other hand, the threshold voltages of the oscillator 21 can also be generated and modulated in analog manners. Please refer to FIG. 6, which also shows an exemplary embodiment of the threshold voltage generator 22 of the present invention. As shown in FIG. 6, the threshold voltage generator 22 includes a first current source 61, a second current source 62, a charge switch 63, a discharge switch 64 and a capacitor C1. The first current source 61 and the second current source 62 are utilized for providing a charge current I1 and a discharge current I2, respectively. The charge switch 63 and the discharge switch 64 are shorted alternatively by control signals clk and clkB those have opposite phases. The capacitor C1 is then charged by the charge current I1 via the charge switch 63 and discharged by the discharge current I2 via the discharge switch 64 to generate at least one of the upper threshold voltage V_{H} and the lower threshold voltage V_{L}. In this case, a smoothly time-varying upper threshold voltage V_{H}, for example, can be generated in a triangular wave form by the fixed charge and discharge currents I1 and I2, so as to jitter the switching frequency signal osc_out generated by the oscillator 21.

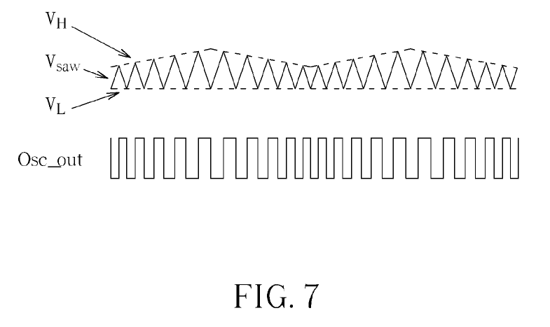

Please further refer to FIG. 7. FIG. 7 is a timing diagram of the upper threshold voltage V_{H}, the lower threshold voltage V_{L}, the saw-tooth wave V_{SAW} and the switching frequency signal osc_out related to FIG. 5 and FIG. 6, in which only the upper threshold voltage V_{H} is varied over time while the lower threshold voltage V_{L} has a fixed value. Likewise, in other embodiments of the present invention, the lower threshold voltage V_{L} can also be modulated to vary over time while the upper threshold voltage V_{H} is fixed, by which the switching frequency of the oscillator 21 can also be jittered.

Please note that the above embodiments of the threshold voltage generator 22 are merely exemplary illustrations of the present invention, those skilled in the art can certainly make appropriate modifications according to practical demands, such as modulating the threshold voltages of the oscillator in other waveform shapes, which also belongs to the scope of the present invention.

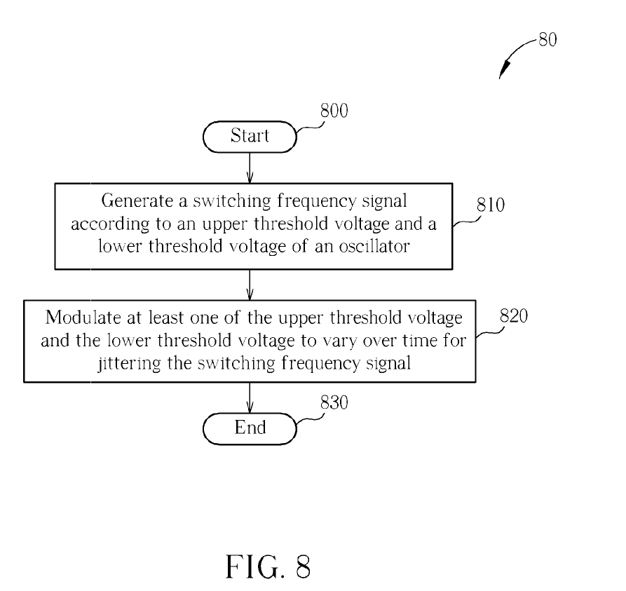

In addition, please refer to FIG. 8. FIG. 8 is a schematic diagram of a frequency jitter process 80 for a PWM controller according to an embodiment of the present invention. The frequency jitter process 80 is utilized for implementing the above PWM controller 20, and includes the following steps:

Step 800: Start.

Step 810: Generate a switching frequency signal according to an upper threshold voltage and a lower threshold voltage of an oscillator.

Step 820: Modulate at least one of the upper threshold voltage and the lower threshold voltage to vary over time for jittering the switching frequency signal.

Step 830: End.

According to the frequency jitter process 80, the switching frequency signal is generated according to the upper threshold voltage and the lower threshold voltage of the oscillator. Then, by modulating at least one of the upper threshold voltage and the lower threshold voltage to vary over time, the switching frequency signal can further be jittered and spread over a larger bandwidth, so as to reduce the EMI generated by a PWM controller. Detailed operations of the PWM controller are already described above, and not narrated again herein.

As mentioned above, by modulating the threshold voltages of the oscillator to vary over time, the operation frequency of the PWM controller can be jittered and spread over a larger bandwidth, so as to minimize the peak value of EMI generated by a switching power supply.

Those skilled in the art will readily observe that numerous modifications and alterations of the device and method may be made while retaining the teachings of the invention.

What is claimed is:

1. A pulse width modulation (PWM) controller with frequency jitter functionality comprising:
an oscillator for generating a switching frequency signal according to an upper threshold voltage and a lower threshold voltage; and
a threshold voltage generator, coupled to the oscillator, for generating the upper threshold voltage and the lower threshold voltage, and modulating at least one of the upper threshold voltage and the lower threshold voltage to vary over time in order for jittering the switching frequency signal.

2. The PWM controller of claim 1, wherein the oscillator comprises:
a saw-tooth wave generator, for generating a saw-tooth wave;
a first comparator, having a positive input terminal coupled to the upper threshold voltage and a negative input terminal coupled to the saw-tooth wave generator, for generating a reset signal when the saw-tooth wave rises to the upper threshold voltage;
a second comparator, having a positive input terminal coupled to the saw-tooth wave generator and a negative input terminal coupled to the lower threshold voltage, for generating a set signal when the saw-tooth wave descends to the lower threshold voltage; and
an RS latch, having a reset terminal coupled to the first comparator and a set terminal coupled to the second comparator, for generating the switching frequency signal according to the reset signal and the set signal;
wherein the switching frequency signal is further fed back to the saw-tooth wave generator for controlling generation of the saw-tooth wave.

3. The PWM controller of claim 2, wherein the RS latch is a NAND type RS latch.

4. The PWM controller of claim 1, wherein the threshold voltage generator is a signal converter, for performing signal conversion on controllable inputs to generate at least one of the upper threshold voltage and the lower threshold voltage.

5. The PWM controller of claim 4, wherein the at least one of the upper threshold voltage and the lower threshold voltage is modulated to vary over time according to the controllable inputs.

6. The PWM controller of claim 1, wherein the threshold voltage generator comprises:
a first current source for providing a charge current;
a second current source for providing a discharge current;
a charge switch;
a discharge switch; and
a capacitor, for being charged by the charge current via the charge switch and discharged by the discharge current via the discharge switch to generate at least one of the upper threshold voltage and the lower threshold voltage.

7. The PWM controller of claim 6, wherein the at least one of the upper threshold voltage and the lower threshold voltage is modulated in a triangular wave form.

8. The PWM controller of claim 1, wherein one of the upper threshold voltage and the lower threshold voltage has a fixed value.

9. A pulse width modulation (PWM) controller with frequency jitter functionality comprising:
an oscillator for generating a switching frequency signal according to an upper threshold voltage and a lower threshold voltage; and
a voltage divider, coupled to the oscillator, for performing a voltage-dividing operation on a power supply voltage to generate the upper threshold voltage and the lower threshold voltage, and modulating both of the upper threshold voltage and the lower threshold voltage to vary over time due to glitches of the power supply voltage those suddenly drop by charging or discharging rear end loads in order for jittering the switching frequency signal.

10. The PWM controller of claim 9, wherein the oscillator comprises:
a saw-tooth wave generator, for generating a saw-tooth wave;
a first comparator, having a positive input terminal coupled to the upper threshold voltage and a negative input terminal coupled to the saw-tooth wave generator, for generating a reset signal when the saw-tooth wave rises to the upper threshold voltage;
a second comparator, having a positive input terminal coupled to the saw-tooth wave generator and a negative input terminal coupled to the lower threshold voltage, for generating a set signal when the saw-tooth wave descends to the lower threshold voltage; and
an RS latch, having a reset terminal coupled to the first comparator and a set terminal coupled to the second comparator, for generating the switching frequency signal according to the reset signal and the set signal;
wherein the switching frequency signal is further fed back to the saw-tooth wave generator for controlling generation of the saw-tooth wave.

11. The PWM controller of claim 10, wherein the RS latch is a NAND type RS latch.

12. A frequency jitter method for a pulse width modulation (PWM) controller comprising:
generating a switching frequency signal according to an upper threshold voltage and a lower threshold voltage; and
modulating at least one of the upper threshold voltage and the lower threshold voltage to vary over time for jittering the switching frequency signal.

13. The frequency jitter method of claim 12, wherein the step of generating the switching frequency signal according to the upper threshold voltage and the lower threshold voltage comprises:
generating a reset signal when a saw-tooth wave rises to the upper threshold voltage;
generating a set signal when the saw-tooth wave descends to the lower threshold voltage; and
generating the switching frequency signal according to the reset signal and the set signal.

14. The frequency jitter method of claim 13, wherein the switching frequency signal is low when the reset signal is received, and the switching frequency signal is high when the set signal is received.

15. The frequency jitter method of claim 12, wherein the upper threshold voltage and the lower threshold voltage are generated by performing a voltage-dividing operation on a power supply voltage.

16. The frequency jitter method of claim 15, wherein both of the upper threshold voltage and the lower threshold voltage are modulated due to glitch of the power supply voltage those suddenly drop by charging or discharging rear end loads.

17. The frequency jitter method of claim 12, wherein at least one of the upper threshold voltage and the lower threshold voltage is generated by performing digital to analog conversion on binary control inputs.

18. The frequency jitter method of claim 17, wherein the at least one of the upper threshold voltage and the lower threshold voltage is modulated to vary over time according to the binary control inputs.

19. The frequency jitter method of claim 12, wherein at least one of the upper threshold voltage and the lower threshold voltage is generated by capacitor charging and discharging.

20. The frequency jitter method of claim 19, wherein the at least one of the upper threshold voltage and the lower threshold voltage is modulated in a triangular wave form.

21. The frequency jitter method of claim 12, wherein one of the upper threshold voltage and the lower threshold voltage has a fixed value.
